(19) United States
(12) Patent Application Publication
(10) Pub. No.: US 2010/0009482 A1
(43) Pub. Date: Jan. 14, 2010

(54) PHOTORESIST COMPOSITION, METHOD OF FORMING A METAL PATTERN, AND METHOD OF MANUFACTURING A DISPLAY SUBSTRATE USING THE SAME

(75) Inventors: Jeong-Min PARK, Seoul (KR); Jung-Soo LEE, Seoul (KR); Doo-Hee JUNG, Seoul (KR); Hi-Kuk LEE, Yongin-si (KR); Deok-Man KANG, Seongnam-si (KR); Sae-Tae OH, Pyeongtaek-si (KR); Sang-Won SON, Cheonan-si (KR); Young-Jin KIM, Anseong-si (KR)

Correspondence Address: H.C. PARK & ASSOCIATES, PLC, 8500 LEESBURG PIKE, SUITE 7500, VIENNA, VA, 22182, US

(73) Assignees: Samsung Electronics Co., Ltd., Suwon-si (KR); AZ Electronic Materials(Japan) K.K., Tokyo (JP)

(21) Appl. No.: 12/419,764

(22) Filed: Apr. 7, 2009

(30) Foreign Application Priority Data
Jul. 11, 2008 (KR) 2008-67324

(51) Int. Cl. H01L 21/02; G03F 7/004; G03F 7/20

(52) U.S. Cl. 438/34; 430/270.1; 430/286.1; 430/280.1; 430/311; 257/E21.002

(57) ABSTRACT

A photoresist composition includes 5% to 50% by weight of an alkali-soluble resin, 0.5% to 30% by weight of a quinone diazide compound, 0.1% to 15 % by weight of a curing agent, and a remainder of an organic solvent. A method of forming a metal pattern includes coating a photoresist composition on a base substrate having a metal layer, and forming a first photoresist film. The photoresist composition includes 5% to 50% by weight of an alkali-soluble resin, 0.5% to 30% by weight of a quinone diazide compound, 0.1% to 15% by weight of a curing agent, and a remainder of an organic solvent. The first photoresist film is patterned, and forms a first photo pattern. The base substrate having the first photo pattern is heated, and forms a first baked pattern. The metal layer is patterned using the first baked pattern, and forms a metal pattern.

### CROSS REFERENCE TO RELATED APPLICATION

This application claims priority from and the benefit of Korean Patent Application No. 2008-67324, filed on Jul. 11, 2008, which is hereby incorporated by reference for all purposes as if fully set forth herein.

### BACKGROUND OF THE INVENTION

1. Field of the Invention

The present invention relates to a photoresist composition, a method of forming a metal pattern, and a method of manufacturing a display substrate using the photoresist composition. Particularly, the present invention relates to a photoresist composition that may be used for manufacturing a display device, a method of forming a metal pattern, and a method of manufacturing a display substrate using the photoresist composition.

2. Discussion of the Background

Generally, a liquid crystal display (LCD) panel includes a display substrate having a thin-film transistor (TFT) as a switching element driving a pixel, an opposite substrate facing the display substrate, and a liquid crystal layer disposed between the display substrate and the opposite substrate.

The display substrate is manufactured through a photolithography process using a photoresist composition. Recently, a process using one mask to pattern two sequentially deposited thin layers may be used instead of using two masks to pattern the thin layers. Particularly, a photo pattern having different thicknesses is formed on a first thin layer and a second thin layer, which are sequentially deposited. The first and second thin layers are firstly patterned using the photo pattern as an etching mask. The second thin layer is secondly patterned using a remaining pattern formed from the photo pattern through an etch-back process. As a result, masks required for an etching process may be reduced, thereby reducing manufacturing costs.

Examples of a photoresist composition include a positive photoresist composition and a negative photoresist composition. When the positive photoresist composition is exposed to light, the exposed portion is removed by a developing solution. When a negative composition is exposed to light, the exposed portion is cured, and the cured portion remains after a developing process. The positive photoresist composition may form a fine pattern. However, since a difference between an exposed portion and an unexposed portion is small, a resolution may be reduced. Furthermore, since a photoresist pattern formed from the positive photoresist composition has a relatively low heat resistance, a shape of the photoresist pattern may be changed through a baking process. Furthermore, an adhesion between the photoresist pattern and a metal layer formed under the photoresist pattern is not strong. Thus, while the metal layer is etched by using the photoresist pattern as an etching mask, undercut may be formed by an etching solution.

In contrast, the negative photoresist composition has relatively great heat resistance and adhesion compared to the positive photoresist composition. However, since the negative photoresist composition has a low stripping ability, resolution of a photoresist pattern may be deteriorated. Furthermore, the negative photoresist composition has a great sensitivity with respect to variation of a baking temperature. Thus, a manufacturing margin may be reduced.

The positive and negative photoresist compositions have different advantages and disadvantages. Thus, further research may resolve the disadvantages of the positive and negative photoresist compositions.

### SUMMARY OF THE INVENTION

The present invention provides a photoresist composition that may improve manufacturing margin, heat resistance, and etching ability.

The present invention also provides a method of forming a metal pattern using the above-mentioned photoresist composition.

The present invention also provides a method of manufacturing a display substrate using the above-mentioned photoresist composition.

Additional features of the invention will be set forth in the description which follows, and in part will be apparent from the description, or may be learned by practice of the invention.

The present invention discloses a photoresist composition including 5% to 50% by weight of an alkali-soluble resin, 0.5% to 30% by weight of a quinone diazide compound, 0.1% to 15% by weight of a curing agent, and a remainder of an organic solvent.

The present invention also discloses a method of forming a metal pattern. In the method, a photoresist composition is coated on a base substrate having a metal layer to form a first photoresist film. The photoresist composition includes 5% to 50% by weight of an alkali-soluble resin, 0.5% to 30% by weight of a quinone diazide compound, 0.1% to 15% by weight of a curing agent, and a remainder of an organic solvent. The first photoresist film is patterned, to form a first photo pattern. The base substrate having the first photo pattern is heated, to form a first baked pattern. The metal layer is patterned using the first baked pattern, to form a metal pattern.

The present invention also discloses a method of manufacturing a display substrate. In the method, a photoresist composition is coated on a base substrate having a gate metal layer to form a first photoresist film. The photoresist composition includes 5% to 50% by weight of an alkali-soluble resin, 0.5% to 30% by weight of a quinone diazide compound, 0.1% to 15% by weight of a curing agent, and a remainder of an organic solvent. The first photoresist film is patterned to form a first photo pattern. The base substrate having the first photo pattern is heated to form a first baked pattern. The gate metal layer is patterned using the first baked pattern to form a gate electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A, FIG. 1B, FIG. 1C, and FIG. 1D are scanning electron microscope (SEM) pictures showing profiles of photoresist patterns baked at different temperatures.

FIG. 2A, FIG. 2B, FIG. 2C, and FIG. 2D are SEM pictures showing profiles of photoresist patterns baked at different temperatures.

FIG. 3A, FIG. 3B, FIG. 3C, FIG. 3D, FIG. 4A, FIG. 4B, FIG. 4C, FIG. 4D, FIG. 4E, FIG. 5, FIG. 6, and FIG. 7 are cross-sectional views showing a method of manufacturing a display substrate according to an exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, exemplary embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Photoresist Composition

A photoresist composition according to an exemplary embodiment of the present invention includes an alkali-soluble resin, a quinone diazide compound, a curing agent and an organic solvent. For example, the photoresist composition may include about 5% to about 50% by weight of an alkali-soluble resin, about 0.5% to about 30% by weight of a quinone diazide compound, about 0.1% to about 15% by weight of a curing agent and a remainder of an organic solvent.

The photoresist composition may further include a photo-acid generator. For example, the photoresist composition may include about 0.01% to about 10% by weight of a photo-acid generator.

The photoresist composition may further include an additive. For example, the photoresist composition may include 0% to about 1% by weight of an additive. For example, the additive may include a surfactant, an adhesion promoter, etc.

(A) Alkali-Soluble Resin

Examples of the alkali-soluble resin may include (A-1) an acryl copolymer, (A-2) a novolac resin, etc.

(A-1) Acryl Copolymer

The acryl copolymer is soluble in alkali. For example, the acryl copolymer may be prepared by copolymerizing monomers including an unsaturated olefin compound and an unsaturated carboxylic acid in the presence of a solvent and a polymerization initiator through a radical polymerizing reaction.

Examples of the unsaturated carboxylic acid may include acrylic acid, methacrylic acid, and the like. These can be used alone or in a combination thereof.

When the content of the unsaturated carboxylic acid is less than about 5% by weight based on a total weight of the monomers, the acryl copolymer may not be dissolved in an alkali solution. When the content of the unsaturated carboxylic acid is more than about 40% by weight based on a total weight of the monomers, a solubility of the acryl copolymer in an alkali solution may be excessively increased. Thus, the content of the unsaturated carboxylic acid may be preferably about 5% to about 40% by weight based on a total weight of the monomers.

Examples of the unsaturated olefin compound may include methyl methacrylate, ethyl methacrylate, N-butyl methacrylate, sec-butyl methacrylate, tert-butyl methacrylate, methyl acrylate, isopropyl acrylate, cyclohexyl methacrylate, 2-methyl cyclohexyl methacrylate, dicyclopentenyl acrylate, dicyclopentanyl acrylate, dicyclopentenyl methacrylate, dicyclopentanyl methacrylate, dicyclopentanyloxyethyl methacrylate, isobonyl methacrylate, cyclohexyl acrylate, 2-methylcyclohexyl acrylate, dicyclopentanyloxyethyl acrylate, isobonyl acrylate, phenyl methacrylate, phenyl acrylate, benzyl acrylate, 2-hydroxyethyl methacrylate, styrene, alpha-methylstyrene, m-methylstyrene, p-methoxystyrene, vinyl toluene, p-methylstyrene, 1,3-butadiene, isoprene, 2,3-dimethyl-1,3-butadiene, etc. These can be used alone or in combination thereof.

The polymerization initiator may include a radical polymerization initiator. Particularly, examples of the polymerization initiator may include 2,2′-azobisisobutylnitrile, 2,2′-azobis(2,4-dimethylvaleronitrile), 2,2′-azobis(4-methoxy-2,4-dimethylvaleronitrile), 1,1′-azobis(cyclohexane-1-carbonitrile), dimethyl 2,2′-azobisisobutylate, and the like.

(A-2) Novolac Resin

The novolac resin is soluble in alkali. For example, the novolac resin may be prepared by reacting a phenol compound with an aldehyde compound or a ketone compound in the presence of an acidic catalyst.

Examples of the phenol compound may include phenol, o-cresol, m-cresol, p-cresol, 2,3-dimethylphenol, 3,4-dimethylphenol, 3,5-dimethylphenol, 2,4-dimethylphenol, 2,6-dimethylphenol, 2,3,6-trimethylphenol, 2-t-butylphenol, 3-t-butylphenol, 4-t-butylphenol, 2-methylresorcinol, 4-methylresorcinol, 5-methylresorcinol, 4-t-butylcatechol, 2-methoxyphenol, 3-methoxyphenol, 2-propylphenol, 3-propylphenol, 4-propylphenol, 2-isopropylphenol, 2-methoxy-5-methylphenol, 2-t-butyl-5-methylphenol, thymol, isothymol, etc. These can be used alone or in a combination thereof.

Examples of the aldehyde compound may include formaldehyde, formalin, p-formaldehyde, trioxane, acetaldehyde, benzaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-chlorobenzaldehyde, m-chlorobenzaldehyde, p-chlorobenzaldehyde, o-methylbenzaldehyde, m-methylbenzaldehyde, p-methylbenzaldehyde, p-ethylbenzaldehyde, p-n-butylbenzaldehyde, terephthalic acid aldehyde, etc. These can be used alone or in a combination thereof.

Examples of the ketone compound may include acetone, methylethylketone, diethyl ketone, diphenyl ketone, etc. These can be used alone or in a combination thereof.

When the content of the alkali-soluble resin is less than about 5% by weight based on a total weight of the photoresist composition, the heat resistance of the photoresist composition may be reduced, thereby deforming a photoresist pattern in a baking process. When the content of the alkali-soluble resin is more than about 50% by weight, an adhesion ability, a sensitivity, a residual ratio, etc. may be reduced. Thus, the content of the alkali-soluble resin may be about 5% to about 50% by weight based on a total weight of the photoresist composition, and may be preferably about 8% to about 30% by weight.

A weight average molecular weight of the alkali-soluble resin may be about 4,000 to 15,000. The weight average molecular weight denotes a polystyrene-reduced weight-average molecular weight measured by gel permeation chromatography (GPC). When the weight average molecular weight of the alkali-soluble resin is less than about 4,000, a photoresist pattern may be damaged by an alkali solution. When the weight average molecular weight of the alkali-soluble resin is greater than about 15,000, a difference between an exposed portion and an unexposed portion of the photoresist pattern may be reduced, thereby a photoresist pattern having a clear shape may not be formed.

(B) Quinone Diazide Compound

The quinone diazide compound may be obtained by reacting a naphthoquinone diazide sulfonate halogen compound with a phenol compound in the presence of a weak base.

The quinone diazide compound may inhibit dissolution of the alkali-soluble resin. Furthermore, the quinone diazide compound may generate an acid by light, and the acid may activate the curing agent.

Examples of the phenol compound may include 2,3,4-trihydroxybenzophenone, 2,4,6-trihydroxybenzophenone, 2,3,4,3′-tetrahydroxybenzophenone, 2,3,4,4′-tetrahydroxybenzophenone, tri(p-hydroxyphenyl)methane, 1,1,1-tri(p-hydroxyphenyl)ethane, 4,4′-[1-[4-[1-[4-hydroxyphenyl]-1-methylethyl]phenyl]ethylidene]diphenol, etc. These can be used alone or in a combination thereof.

Examples of the naphthoquinone diazide sulfonate halogen compound may include 1,2-quinonediazide-4-sulfonic ester, 1,2-quinonediazide-5-sulfonic ester, 1,2-quinonediazide-6-sulfonic ester, etc.

When the content of the quinone diazide compound is less than about 0.5% by weight based on a total weight of the photoresist composition, solubility of an unexposed portion may increase, and thereby a photoresist pattern may not be formed. When the content of the quinone diazide compound is more than about 30% by weight, solubility of an exposed portion may be reduced, and thereby a developing process may not be performed. Thus, the content of the quinone diazide compound may be about 0.5% to about 30% by weight, and may be preferably about 3% to about 15% by weight.

(C) Curing Agent

The curing agent may react with the alkali-soluble resin to cross-link the alkali-soluble resin. The curing agent may be activated by an acid generated when the quinone diazide compound is exposed to light. The curing agent may be coupled to the alkali-soluble resin by heat.

Examples of the curing agent may include an epoxy resin, a polyglycidyl ether resin, a diphenyl ether resin, a styrene resin, a melamine resin, etc.

The epoxy resin contains at least one epoxy group. Examples of the epoxy resin may include bisphenol A epoxy resin, bisphenol F epoxy resin, novolac epoxy resin, cycloaliphatic epoxy resin, etc. Examples of the diphenyl ether resin may include diphenyl ether, 1,3-diphenoxy benzene, 1,2-diphenoxy benzene, etc. Examples of the styrene resin may include polyphenylethylene, polychlorotrifluoroethylene, etc. Examples of the melamine resin may include alkoxymethylated melamine resin, ethoxymethylated melamine resin, propoxymethylated melamine resin, butoxymethylated melamine resin, Cymel® (manufactured by Cytec Industries), etc.

When the content of the curing agent is less than about 0.1% by weight based on a total weight of the photoresist composition, a cross-linking reaction may not be performed when a photoresist composition is exposed to light. When the content of the curing agent is more than about 15% by weight, the photoresist composition may be easily hardened by heat. Thus, a restoring stability may be deteriorated. Particularly, the content of the curing agent may be about 0.5% to about 3% by weight.

(D) Organic Solvent

Examples of the organic solvent may include ethers, glycol ethers, ethylene glycol alkyl ether acetates, diethylene glycols, propylene glycol monoalkyl ethers, propylene glycol alkyl ether acetates, aromatic compounds, ketones, ester compounds, etc.

When the content of the organic solvent is less than about 45% by weight based on a total weight of the photoresist composition, dropping and coating the photoresist composition may be difficult. When the content of the organic solvent is more than about 90% by weight, forming a photoresist film having a predetermined thickness may be difficult.

(E) Photo-Acid Generator

The photo-acid generator generates an acid when exposed to light. The acid generated by the photo-acid generator may activate the curing agent. When the photoresist composition further includes the photo-acid generator, the photo-acid generator may further promote activation of the curing agent with the acid generated by the quinone diazide compound.

Examples of the photo-acid generator may include benzophenone derivatives, triazine derivatives, sulfonium derivatives, etc.

When the content of the photo-acid generator is less than about 0.01% by weight based on a total weight of the photoresist composition, an amount of an acid generated by the photo-acid generator may be small, thereby barely activating the curing agent. When the content of the photo-acid generator is more than about 10% by weight, an amount of an acid generated by the photo-acid generator may be excessive. Thus, a developing speed may be reduced, or a photoresist pattern having a clear shape may not be formed. Thus, the content of the photo-acid generator may be about 0.01% to about 10% by weight. Preferably, the content of the photo-acid generator may be about 0.1% to about 1% by weight.

(E) Additive

The surfactant may improve coating characteristics and development characteristics of the photoresist composition. Examples of the surfactant may include polyoxyethylene octylphenylether, polyoxyethylene nonylphenylether, F171, F172, F173 (TM, manufactured by Dainippon Ink in Japan), FC430, FC431 (TM, manufactured by Sumitomo 3M in Japan), KP341 (TM, manufactured by Shin-Etsu Chemical in Japan), etc. These can be used alone or in a combination thereof.

The adhesion promoter agent may improve an adhesion between a substrate and a photoresist pattern formed from the photoresist composition. Examples of the adhesion promoter may include a silane coupling agent containing a reactive substitution group such as a carboxyl group, a methacrylic group, an isocyanate group, an epoxy group, etc. Particularly, examples of the silane coupling agent may include γ-methacryloxypropyl trimethoxy silane, vinyl triacetoxy silane, vinyl trimethoxy silane, γ-isocyanate propyl triethoxy silane, γ-glycidoxy propyl trimethoxy silane, β-(3,4-epoxy cyclohexyl)ethyl trimethoxy silane, etc. These can be used alone or in a combination thereof.

The content of the additive may depend on the contents of the alkali-soluble resin, the quinone diazide compound, the curing agent, and the organic solvent. For example, the content of the additive may be about 0 to about 1% by weight of the photoresist composition, in order to prevent the additive from affecting the function of the quinone diazide compound and the curing agent.

Hereinafter, a photoresist composition according to an exemplary embodiment of the present invention will be more fully described with reference to the following particular examples and comparative examples.

### EXAMPLE 1

A phenol mixture including m-cresol and p-cresol in a weight ratio of about 40:60 was reacted with formaldehyde to prepare an alkali-soluble resin, of which a weight average molecular weight was about 12,000. About 16.25% by weight of the alkali-soluble resin, about 7.5% by weight of a quinone diazide compound prepared by reacting 1,2-naphtoquinondiazide-4-sufonic ester and 2,3,4,4′-tetrahydroxybenzophenone, about 1.25% of hexamethoxymethylmelamine as a curing agent and about 75% by weight of propylene glycol monomethyl ether acetate as an organic solvent were mixed with each other. The mixture solution was filtrated using a pore filter having pores of about 0.2 μm to thereby obtain a photoresist composition having a viscosity of about 15 cP (centipoise).

### EXAMPLE 2

A phenol mixture including m-cresol and p-cresol in a weight ratio of about 40:60 was reacted with formaldehyde to prepare an alkali-soluble resin, of which a weight average molecular weight was about 12,000. About 16.09% by weight of the alkali-soluble resin, about 7.43% by weight of a quinone diazide compound prepared by reacting 1,2-naphtoquinondiazide-5-sufonic ester and 2,3,4,4′-tetrahydroxybenzophenone, about 1.24% of hexamethoxymethylmelamine as a curing agent, about 0.24% by weight of a triazine derivative, and about 75% by weight of propylene glycol monomethyl ether acetate as an organic solvent were mixed with each other. The mixture solution was filtrated using a pore filter having pores of about 0.2 μm to thereby obtain a photoresist composition having a viscosity of about 15 cP.

### COMPARATIVE EXAMPLE 1

A phenol mixture including m-cresol and p-cresol in a weight ratio of about 40:60 was reacted with formaldehyde to prepare an alkali-soluble resin, of which a weight average molecular weight was about 12,000. About 17.5% by weight of the alkali-soluble resin, about 7.5% by weight of a quinone diazide compound prepared by reacting 1,2-naphtoquinondiazide-5-sufonic ester and 2,3,4,4′-tetrahydroxybenzophenone, and about 75% by weight of propylene glycol monomethyl ether acetate as an organic solvent were mixed with each other. The mixture solution was filtrated using a pore filter having pores of about 0.2 μm to thereby obtain a photoresist composition having a viscosity of about 15 cP.

Evaluation of Characteristics of Photoresist Patterns

Each photoresist composition of Examples 1, Examples 2, and Comparative Example 1 was coated on a substrate having a triple-layer including a first molybdenum layer, an aluminum layer and a second molybdenum layer to form a photoresist film. The photoresist film was exposed to light, and then developed using tetra methyl ammonium hydroxide solution to form a photoresist pattern. Thereafter, the substrate having the photoresist pattern was disposed under MPA-2000 (TM, manufactured by Canon, Inc. in Japan) as an exposure apparatus. The substrate was exposed to light at about 80 mJ while being moved at a speed of about 26 mm/s. Thereafter, the substrate was heated at about 130° C.

(1) Measuring an Exposure Time

In the exposure process, an exposure time was measured by FX-601 (TM, manufactured by Nikon in Japan) until the photoresist pattern had a desired critical dimension. Thus the results obtained are shown in the following Table 1.

(2) Evaluation of Heat Resistance

A first profile angle of the photoresist pattern was measured after the photoresist pattern was exposed to light, and a second profile angle of the photoresist pattern was measured after the photoresist pattern was heated. Thus the results obtained are shown in the following Table 1. In Table 1, “O” represents that a difference between the first and second profile angles was less than 1°, “Δ” represents that a difference between the first and second profile angles was in a range of 1° to about 5°, “X” represents that a difference between the first and second profile angles was more than 5°.

(3) Evaluation of Residual Ratio

An initial thickness (a) of the photoresist film was measured, and a thickness (b) of the photoresist pattern was measured. A residual ratio (c) was obtained by the following Formula 1, and is shown in the following Table 1.

c=b/a*100 <Formula 1>

(4) Evaluation of Etching Resistance

The triple layer was etched by using an etching solution including phosphoric acid, nitric acid and acetic acid and using the baked photoresist pattern as an etching mask. After a lapse of about 100 seconds, a corroded thickness of a portion of the triple layer, which was covered by the photoresist pattern, was measured. The results obtained are shown in the following Table 1.

TABLE 1

| | Exposure time | Residual ratio | Heat | Etching |
|---|---|---|---|---|
| | (ms: 1/1000 sec) | (%) | resistance | resistance |
| Example 1 | 1000 | 98 | Δ | 0.50 |
| Example 2 | 1100 | 98 | ◯ | 0.45 |
| Comparative | 1300 | 98 | X | 0.60 |
| Example 1 | | | | |

Referring to Table 1, it can be noted that the exposure time of the photoresist pattern of Comparative Example 1 was relatively long compared to the photoresist patterns of Examples 1 and 2. Thus, it can be noted that the photoresist compositions of Examples 1 and 2, which include a curing agent, have relatively great photo-sensitivity compared to a conventional photoresist composition.

Furthermore, it can be noted that the residual ratio of the photoresist pattern of Comparative Example 1 was substantially equal to the photoresist patterns of Examples 1 and 2. Thus, it can be noted that the curing agent does not deteriorate a residual ratio of a photoresist pattern.

Furthermore, the photoresist pattern of Comparative Example 1 reflowed after the photoresist pattern was baked so that the difference between the first and second profile angles was more than 5°. In contrast, the difference between the first and second profile angles of the photoresist pattern of Example 1 was in a range of 1° to about 5°. Thus, it can be noted that the heat resistance of the photoresist pattern may be improved by the curing agent. The difference between the first and second profile angles of the photoresist pattern of Example 2 was less than 1°. Thus, it can be noted that the heat resistance of the photoresist pattern of Example 2 may be further improved with respect to photoresist patterns of Example 1 and Comparative Example 1.

The photoresist composition of Example 2 further included a photo-acid generator compared to photoresist composition of Example 1. Thus, it can be noted that the photo-acid generator may promote activation of the curing agent, thereby promoting cross-linking of the alkali-soluble resin, thereby improving the heat resistance of the photoresist pattern compared to Example 1.

Furthermore, the corroded thickness of the triple layers under the photoresist patterns of Examples 1 and 2 was relatively small with respect to the triple layer under the photoresist pattern of Comparative Examples 1. Thus, it can be noted that the curing agent activated by light may improve an adhesion between the photoresist pattern and the triple layer, and improve an etching resistance.

Experiment 1

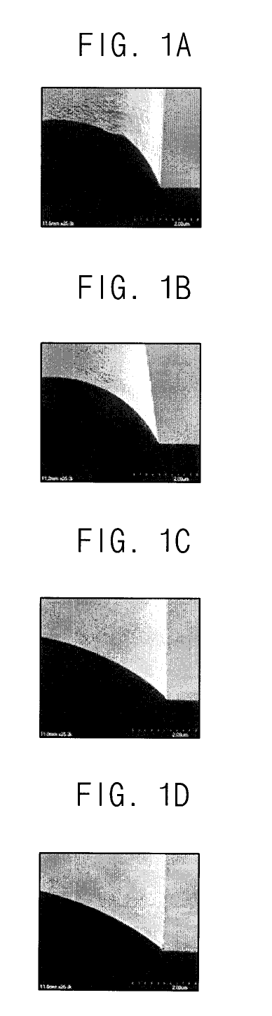

Photoresist patterns were formed from the photoresist composition of Example 2 through a coating process, an exposing process, and a developing process. Thereafter, the photoresist patterns were baked at different temperatures, and then pictured by a scanning electron microscope (SEM). FIG. 1A is an SEM picture of the photoresist pattern baked at about 115° C. FIG. 1B is an SEM picture of the photoresist pattern baked at about 120° C. FIG. 1C is an SEM picture of the photoresist pattern baked at about 125° C. FIG. 1D is an SEM picture of the photoresist pattern baked at about 130° C.

FIG. 1A, FIG. 1B, FIG. 1C, and FIG. 1D are SEM pictures showing profiles of photoresist patterns baked at different temperatures.

Referring to FIG. 1A, FIG. 1B, FIG. 1C, and FIG. 1D, it can be noted that the photoresist patterns formed from the photoresist composition of Example 2 may reflow at a high temperature when the photoresist patterns were baked after being developed. Particularly, it can be noted that a side of the photoresist pattern was deformed at a temperature greater than or equal to about 120° C.

Experiment 2

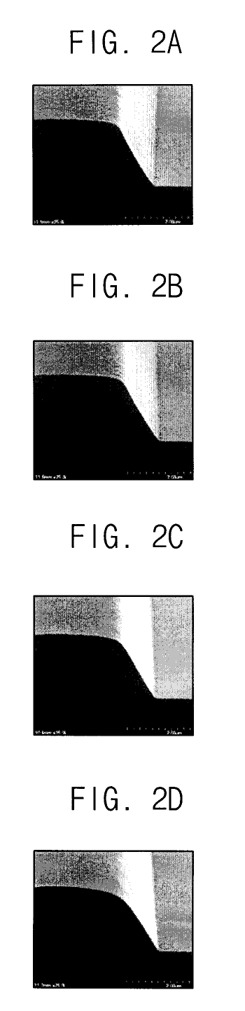

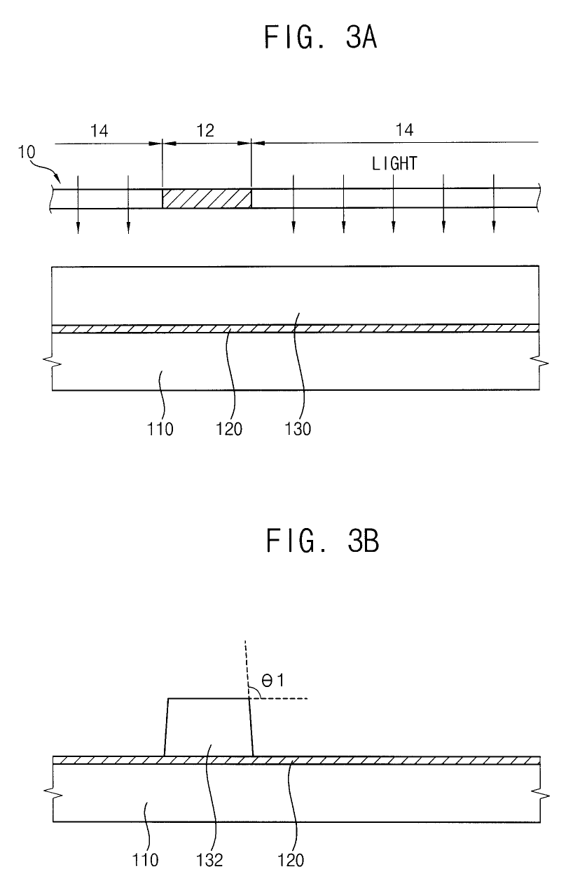

Photoresist patterns were formed from the photoresist composition of Example 2 through a coating process, an exposing process, and a developing process. Thereafter, the photoresist patterns were disposed under MPA-2000 (TM, manufactured by Canon, Inc. in Japan). The photoresist patterns were exposed to light at about 80 mJ while being moved at a speed of about 26mm/s. Thereafter, the photoresist patterns were baked at different temperatures, and then pictured by a scanning electron microscope (SEM). FIG. 2A is an SEM picture of the photoresist pattern baked at about 115° C. FIG. 2B is an SEM picture of the photoresist pattern baked at about 120° C. FIG. 2C is an SEM picture of the photoresist pattern baked at about 125° C. FIG. 2D is an SEM picture of the photoresist pattern baked at about 130° C.

FIG. 2A, FIG. 2B, FIG. 2C, and FIG. 2D are SEM pictures showing profiles of photoresist patterns baked at different temperatures.

Referring to FIG. 2A, FIG. 2B, FIG. 2C, and FIG. 2D, the photoresist patterns did not reflow when the baking temperature was increased from 115° C. to about 130° C. Thus, it may be noted that the quinone diazide compound and the photo-acid generator generates an acid, thereby activating the curing agent, thereby promoting cross-linking the alkali-soluble resin so that the heat resistance of the photoresist patterns may be improved.

The photoresist composition according to an exemplary embodiment of the present invention may have a high heat resistance and a high etching resistance, which are characteristics of a negative photoresist composition, as well as a great resolution, which is a characteristic of a positive photoresist composition. Thus, using the photoresist composition may improve the reliability of etching a thin layer under a photoresist pattern formed from the photoresist composition.

Hereinafter, a method of manufacturing a display substrate according to an exemplary embodiment of the present invention will be more fully described with reference to the accompanying drawings.

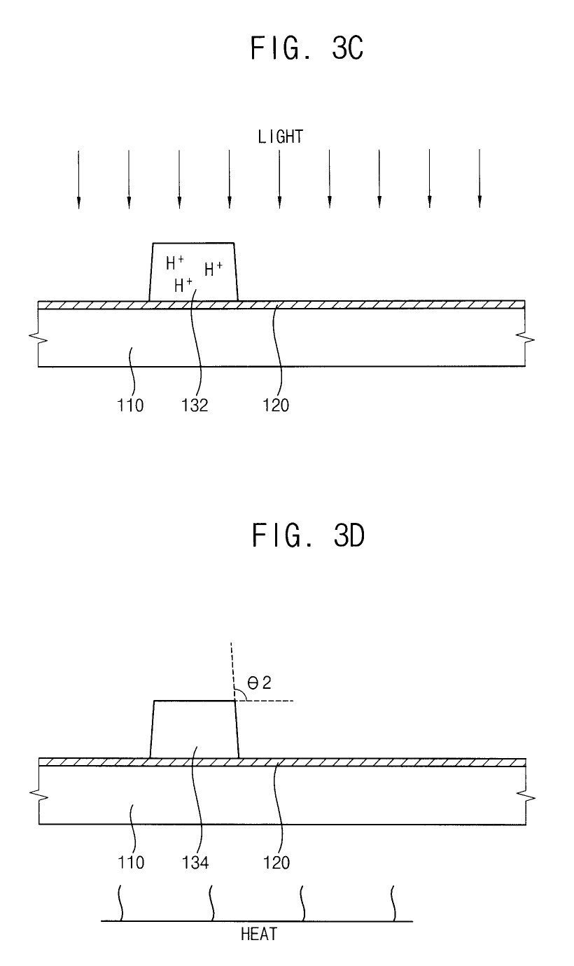

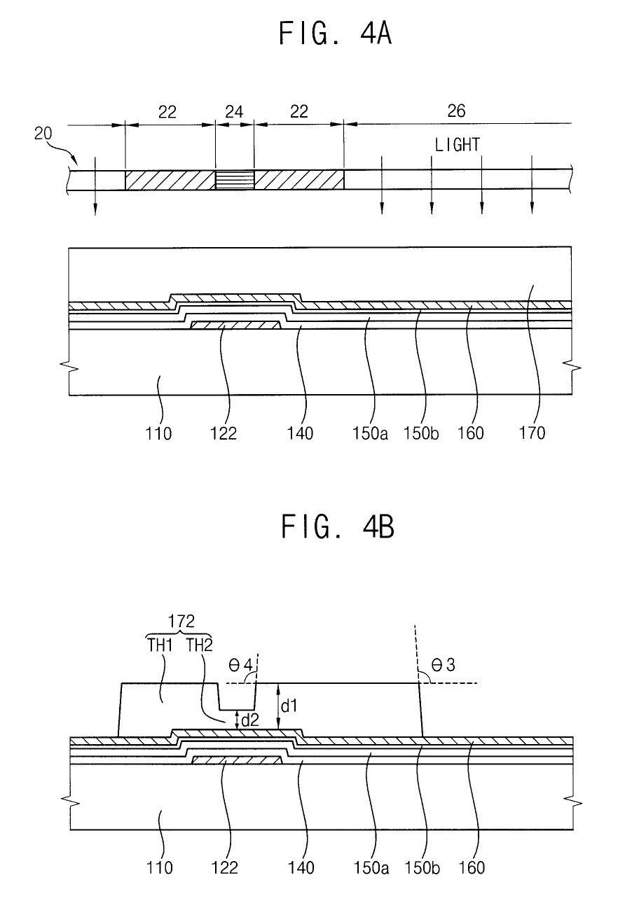

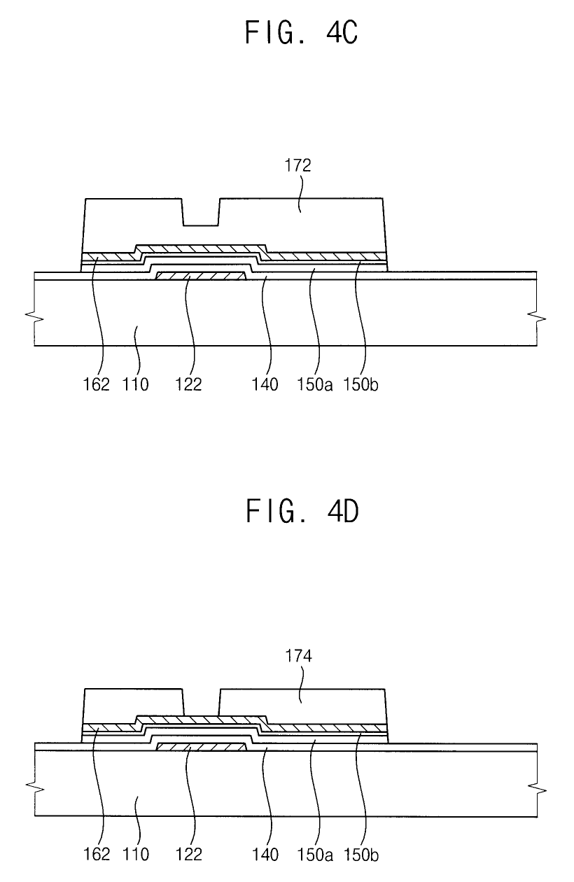

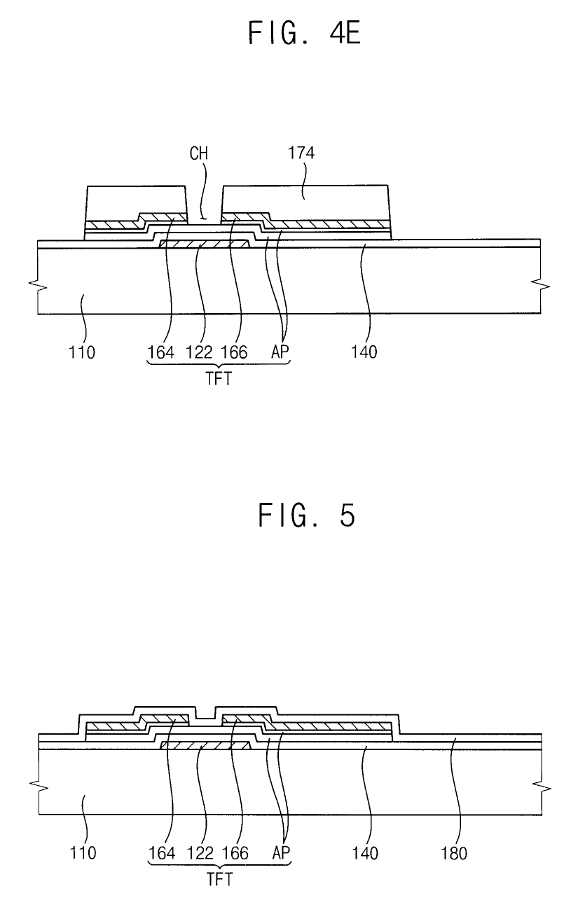

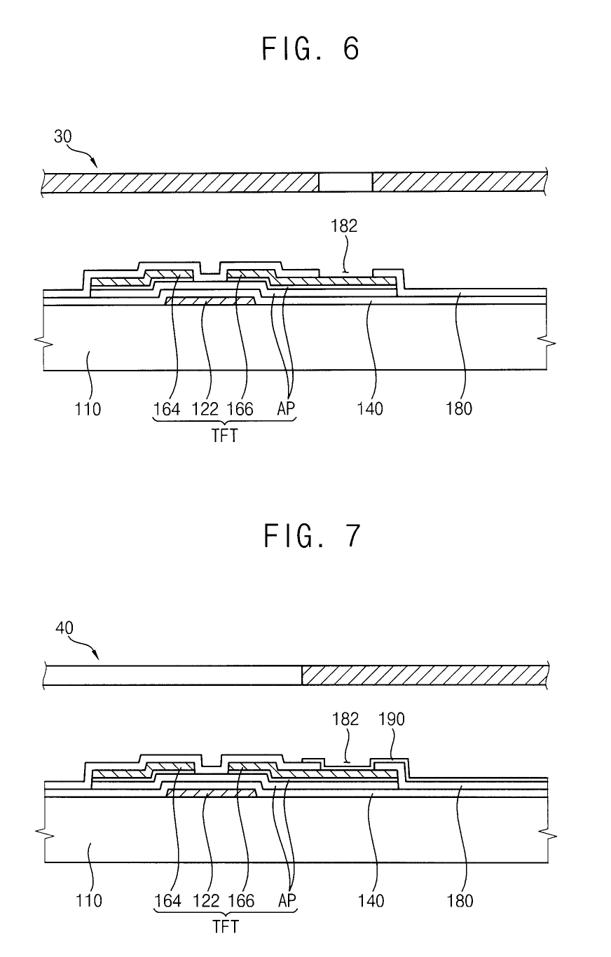

FIG. 3A, FIG. 3B, FIG. 3C, FIG. 3D, FIG. 4A, FIG. 4B, FIG. 4C, FIG. 4D, FIG. 4E, FIG. 5, FIG. 6 and FIG. 7 are cross-sectional views showing a method of manufacturing a display substrate according to an exemplary embodiment of the present invention.

FIG. 3A, FIG. 3B, FIG. 3C, and FIG. 3D are cross-sectional views showing formation of a gate pattern.

Referring to FIG. 3A, a gate metal layer 120 and a first photoresist film 130 are formed on a base substrate 110.

Examples of a material that may be used for the base substrate 110 may include glass, soda lime, etc.

The gate metal layer 120 may be formed on the base substrate 110 through a sputtering process. The gate metal layer 120 may have a single-layer structure or a multilayer structure including at least two metal layers having different physical characteristics. Examples of a material that may be used for the gate metal layer 120 may include aluminum (Al), molybdenum (Mo), neodymium (Nd), chromium (Cr), tantalum (Ta), titanium (Ti), tungsten (W), copper (Cu), silver (Ag), an alloy thereof, etc. For example, the gate metal layer 120 may have a triple-layered structure including a lower Mo layer, an Al layer, and an upper Mo layer, which are sequentially deposited, so as to reduce resistance.

The first photoresist film 130 may be formed by dropping a photoresist composition on the gate metal layer 120 and coating the photoresist composition. For example, the photoresist composition may be coated on the gate metal layer 120 through a spin coating method or a slit coating method.

The photoresist composition may include about 5% to about 50% by weight of an alkali-soluble resin, about 0.5% to about 30% by weight of a quinone diazide compound, about 0.1% to about 15% by weight of a curing agent, and a remainder of an organic solvent. For example, the photoresist composition may include about 0.01% to about 10% by weight of a photo-acid generator. The photoresist composition may be substantially the same as the photoresist composition explained at the above. Thus, any further explanation will be omitted.

A first mask 10 is disposed on the base substrate 110 having the first photoresist film 130, and light is irradiated onto the base substrate 110 through the first mask 10 to expose the first photoresist film 130 to the light. For example, the light may be UV ray. The first mask 10 includes a first light-blocking portion 12 to block light and a first light-transmitting portion 14 to transmit light. The first photoresist film 130 is exposed to the light transmitted through the first light-transmitting portion 14.

Referring to FIG. 3B, the first photoresist film 130 is developed by using a developing solution to form a first photo pattern 132.

The alkali-soluble resin in an exposed portion of the first photoresist film 130 may be dissolved by the developing solution. The alkali-soluble resin in an unexposed portion of the first photoresist film 130 may not be dissolved by the developing solution since the quinone diazide compound may inhibit dissolution of the alkali-soluble resin. Thus, the unexposed portion of the first photoresist film 130 may remain. As a result, the first photo pattern 132 may be formed on a gate line portion and a gate electrode portion of the gate metal layer 120.

An angle between an upper surface of the base substrate 110 and a side surface of the first photo pattern 132 is defined as a first angle θ₁. The first angle θ₁ may be equal to or greater than about 90°.

Referring to FIG. 3C, the base substrate 110 having the first photo pattern 132 is disposed on a stage of an exposure device, and the first photo pattern 132 is entirely exposed to light by the exposure device. For example, the exposure device may be MPA-2000 (trade name; manufactured by Canon, Inc. in Japan). For example, a light source of the exposure device may be a halogen lamp.

When the first photo pattern 132 is exposed to light, an acid is generated in the first photo pattern 132, and the curing agent may be activated by the acid. The acid may be generated when the quinone diazide compound is exposed to light. When the photoresist composition further includes the photo-acid generator, the acid may be generated by the quinone diazide compound and the photo-acid generator. For example, the quinone diazide compound and the photo-acid generator may generate the acid by exposure to light of about 50 mJ to about 150 mJ. More particularly, the quinone diazide compound and the photo-acid generator may generate the acid by exposure to light of about 70 mJ to about 90 mJ.

When an area, onto which the exposure device may irradiate light, is equal to or greater than an area of the base substrate 110, the first photo pattern 132 may be completely exposed to light by irradiating light one time. However, when the area, onto which the exposure device may irradiate light, is less than the area of the base substrate 110, at least one of the stage of the exposure device and the light source of the exposure device needs to move to expose the first photo pattern 132 to light. For example, the light source may be secured, and the stage may move at a speed of about 26 mm/s to expose the first photo pattern 132 to light.

Referring to FIG. 3D, the base substrate 110 having the first photo pattern 132 is baked to form a first baked pattern 134. The first photo pattern 132 may be baked at about 100° C. to about 150° C. When the first photo pattern 132 is baked, the curing agent in the first photo pattern 132 is activated to react with the alkali-soluble resin to cross-link the alkali-soluble resin. The cross-linked alkali-soluble resin may form a net-shaped structure to form the first baked pattern 134.

When an angle between an upper surface of the base substrate 110 and a side surface of the first baked pattern 134 is defined as a second angle θ₂, the first angle θ₁ may be substantially equal to the second angle θ₂, or a difference between the first angle θ₁ and second angle θ₂ may be less than 5°. Particularly, the first based pattern 134 may not reflow through the baking process. As a result, the second angle θ₂ may be substantially equal to the first angle θ₁ of the first photo pattern 132. Therefore, the photoresist composition according to an example embodiment of the present invention may improve a heat resistance of the first baked pattern 134.

Thereafter, the gate metal layer 120 is patterned by using the first based pattern 134 as an etching mask to form a gate line and a gate electrode, and the first baked pattern 134 is removed by a stripping solution. The gate metal layer 120 may be patterned by using an etching solution including a strong acid. When the gate metal layer 120 is etched by the etching solution, damage to a portion of the gate metal layer 120, which makes contact with the first baked pattern 134, may be minimized since an adhesion between the first baked pattern 134 and the gate metal layer 120 is strong.

FIG. 4A, FIG. 4B, FIG. 4C, FIG. 4D, FIG. 4E, and FIG. 5 are cross-sectional views showing formation of a data pattern.

Referring to FIG. 4A, a gate insulation layer 140, a semiconductor layer 150a, an ohmic contact layer 150b, a data metal layer 160, and a second photoresist film 170 are sequentially formed on the base substrate 110 having a gate electrode 122 formed from the gate metal layer 120.

The gate electrode portion of the gate metal layer 120 remains to form the gate electrode 122, and is connected to a gate line (not shown) that extends in a first direction on the base substrate 110. The gate line portion of the gate metal layer 120 remains to form the gate line.

The gate insulation layer 140 is formed on the gate electrode 122 and the gate line. For example, the gate insulation layer may include silicon nitride, etc.

The semiconductor layer 150a is formed on the gate insulation layer 140, and the semiconductor layer 150a may include, for example, amorphous silicon. The ohmic contact layer 150b is formed on the semiconductor layer 150a, and the ohmic contact layer 150b may include, for example, amorphous silicon, into which n⁺ impurities are implanted at a high concentration.

The data metal layer 160 is formed on the ohmic contact layer 150b. The data metal layer 160 may have a single-layer structure or a multilayer structure including at least two metal layers having different physical characteristics. Examples of a material that may be used for the data metal layer 160 may include aluminum (Al), molybdenum (Mo), neodymium (Nd), chromium (Cr), tantalum (Ta), titanium (Ti), tungsten (W), copper (Cu), silver (Ag), an alloy thereof, etc. For example, the data metal layer 160 may have a triple-layered structure including a lower Mo layer, an Al layer, and an upper Mo layer, which are sequentially deposited, or a double-layered structure including an Al layer, and a Mo layer, which are sequentially deposited.

The second photoresist film 170 is formed on the data metal layer 160. The second photoresist film 170 is formed by using the photoresist composition. A method of forming the second photoresist film 170 may be substantially the same as the method of forming the first photoresist film 120. Thus, any further explanation will be omitted.

A second mask 20 is disposed on the base substrate 110 having the second photoresist film 170, and light is irradiated onto the base substrate 110 through the second mask 20 to expose the second photoresist film 170 to the light.

The second mask 20 includes a second light-blocking portion 22 to block light, a semi-transmitting portion 24 to partially transmit light, and a second light-transmitting portion 26 to transmit light. The light passing through the second light-transmitting portion 26 is irradiated onto the second photoresist film 170 so that the quinone diazide compound exposed to light becomes soluble in an alkali solution. Thus, the exposed portion of the second photoresist film 170 may be removed by a developing solution. The quinone diazide compound in an unexposed portion of the second photoresist film 170 corresponding to the second light-blocking portion 22 inhibits dissolution of the alkali-soluble resin. Thus, the unexposed portion of the second photoresist film 170 may remain after the developing process. The quinone diazide compound in a semi-exposed portion of the second photoresist film 170 corresponding to the semi-transmitting portion 24 becomes partially soluble in an alkali solution, and partially inhibits dissolution of the alkali-soluble resin. Thus, the semi-exposed portion of the second photoresist film 170 is partially removed.

Referring to FIG. 4B, the second photoresist film 170 is developed to form a second photo pattern (not shown), and the second photo pattern is entirely exposed to light, and baked to form a second baked pattern 172. Exposing and baking the second photo pattern may be substantially the same as exposing and baking the first photo pattern. Thus, any further explanation will be omitted.

A third angle θ₃ and a fourth angle θ₄ between an upper surface of the base substrate 110 and side surfaces of the second baked pattern 172 may be substantially equal to a fifth angle (not shown) between an upper surface of the base substrate 110 and a side surface of the second photo pattern, or a difference between the fifth angle and the third angle θ3 and fourth angle θ₄ may be less than 5°.

The second baked pattern 172 includes a first portion TH1 having a first thickness d1 and a second portion TH2 having a second thickness d2. The second thickness d2 is less than the first thickness d1. The first portion TH1 is formed on a source electrode portion, a drain electrode portion and a data line portion of the data metal layer 160, and the second portion TH2 is formed on an apart portion of the data metal layer 160. The photoresist composition according to an example embodiment of the present invention may improve a heat resistance of the second baked pattern 172.

Referring to FIG. 4C, the data metal layer 160 is etched by using the second baked pattern 172 as an etching mask to form a data line (not shown) and a switching pattern 162.

The data line portion of the data metal layer 160 is protected by the first portion TH1, and this part remains to form the data line. The source electrode portion and the drain electrode portion are protected by the first portion TH1, and the apart portion is protected by the second portion TH2. Therefore, the source electrode portion, the drain electrode portion and the apart portion remain to form the switching pattern 162. The switching pattern 162 is connected to the data line. Since an adhesion between the second baked pattern 172 and the data metal layer 160 is strong, damage to the data line and the switching pattern 162 may be minimized.

Thereafter, the ohmic contact layer 150b and the semiconductor layer 150a are patterned by using the second baked pattern 172, the data line, and the switching pattern 162 as an etching mask.

Referring to FIG. 4D, the second baked pattern 172 is etched-back to form a remaining pattern 174. Particularly, the second portion TH2 of the second baked pattern 172 is removed, and the first portion TH1 is reduced by the second portion TH2 to form the remaining pattern 174. The remaining pattern 174 exposes the apart portion of the switching pattern 162.

Referring to FIG. 4E, an exposed portion of the switching pattern 162 is etched to form a source electrode 164 connected to the data line and a drain electrode 166 spaced apart from the source electrode 164. While the switching pattern 162 is etched, damage to the switching pattern 162 may be minimized since an adhesion between the remaining pattern 174 and the switching pattern 162 is strong.

Thereafter, a portion of the ohmic contact layer 152b, which is exposed between the source electrode 164 and the drain electrode 166, is removed by using the remaining pattern 174, the source electrode 164, and the drain electrode 166 as an etching mask. As a result, an active pattern AP is formed on the gate insulation layer 140, and a channel portion CH of a thin-film transistor TFT is formed. The thin-film transistor TFT includes the gate electrode 122, the source electrode 164, the drain electrode 166, and the active pattern AP.

The photoresist composition according to an exemplary embodiment of the present invention may form a photoresist pattern having a clear shape, and may improve a heat resistance and an adhesion with a metal layer. Thus, the reliability of forming the gate electrode 122, the gate line, the data line, the source electrode 154, and the drain electrode 166 may be improved.

Referring to FIG. 5, the remaining pattern 174 is removed by using a stripping solution. Thereafter, a passivation layer 180 is formed on the base substrate 110 having the thin-film transistor TFT. For example, the passivation layer 180 may include silicon nitride, etc.

Referring to FIG. 6, a third photoresist film (not shown) is formed on the passivation layer 180, and is exposed to light by using a third mask 30 to form a third photo pattern. A portion of the passivation layer 180 is etched by using the third photo pattern as an etching mask to form a contact hole 182 exposing a portion of the drain electrode 166. The third photo pattern may be removed by a stripping solution.

The third photoresist film may be formed from a conventional positive photoresist composition. Alternatively, the third photoresist film may be formed from the photoresist composition according to an exemplary embodiment of the present invention.

Alternatively, an organic layer (not shown) may be formed on the passivation layer 180, and the third mask 30 may be disposed on the organic layer to expose the organic layer to light so as to form a contact hole in the passivation layer 180 and in the organic layer. The organic layer may remain on the base substrate 110 having the thin-film transistor TFT to planarize the base substrate 110. For example, the organic layer may be formed from a composition including a photo-sensitive material.

Referring to FIG. 7, a pixel electrode 190 is formed on the base substrate 110 having the passivation layer 180.

For example, a transparent electrode layer (not shown) and a fourth photoresist film (not shown) are formed on the base substrate 110, and a fourth mask 40 is disposed on the fourth photoresist film. Light is irradiated onto the base substrate 110 through the fourth mask 40 to expose the fourth photoresist film, to illuminate and develop the fourth photoresist film. As a result, a fourth photo pattern is formed. The transparent electrode layer is patterned by using the fourth photo pattern as an etching mask to form the pixel electrode 190. The pixel electrode 190 may make contact with the drain electrode 160 through the contact hole 182, and may be connected to the thin-film transistor TFT.

For example, the transparent electrode layer may include indium tin oxide (ITO), indium zinc oxide (IZO), etc. The fourth photoresist film may be formed from a conventional positive composition or the photoresist composition according to an exemplary embodiment of the present invention.

In an exemplary embodiment, the passivation layer 180 and the transparent electrode layer are respectively patterned by using different masks. However, the passivation layer 180 and the transparent electrode layer may be patterned by using a same photoresist pattern formed from a negative photoresist composition.

According to the above, a photoresist composition according to an exemplary embodiment of the present invention may have a high heat resistance and a high etching resistance, which are characteristics of a negative photoresist composition, as well as a great resolution, which is a characteristic of a positive photoresist composition. Thus, using the photoresist composition may improve the reliability of etching a thin layer under a photoresist pattern formed from the photoresist composition thereby improving manufacturing reliability.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A photoresist composition, comprising:
5% to 50% by weight of an alkali-soluble resin;
0.5% to 30% by weight of a quinone diazide compound;
0.1% to 15% by weight of a curing agent; and
a remainder of an organic solvent.

2. The photoresist composition of claim 1, wherein the quinone diazide compound is prepared by reacting a naphthoquinone diazide sulfonate halogen compound with a phenol compound.

3. The photoresist composition of claim 1, wherein the naphthoquinone diazide sulfonate halogen compound comprises at least one selected from the group consisting of 1,2-quinonediazide-4-sulfonic ester, 1,2-quinonediazide-5-sulfonic ester, and 1,2-quinonediazide-6-sulfonic ester.

4. The photoresist composition of claim 2, wherein the phenol compound comprises at least one selected from the group consisting of 2,3,4-trihydroxybenzophenone, 2,4,6-trihydroxybenzophenone, 2,3,4,3′-tetrahydroxybenzophenone, 2,3,4,4′-tetrahydroxybenzophenone, tri(p-hydroxyphenyl)methane, 1,1,1-tri(p-hydroxyphenyl)ethane, and 4,4′-[1-[4-[1-[4-hydroxyphenyl]-1-methylethyl]phenyl]ethylidene]diphenol.

5. The photoresist composition of claim 1, wherein the quinone diazide compound generates an acid in response to a light of 50 mJ to 150 mJ.

6. The photoresist composition of claim 1, wherein the curing agent is coupled to the alkali-soluble resin by heat.

7. The photoresist composition of claim 1, wherein the curing agent comprises at least one selected from the group consisting of an epoxy resin, a diphenyl ether resin, a styrene resin, and a melamine resin.

8. The photoresist composition of claim 1, wherein the alkali-soluble resin comprises at least one selected from the group consisting of an acryl copolymer and a novolac resin.

9. The photoresist composition of claim 1, further comprising 0.01% to 10% by weight of a photo-acid generator.

10. A method of forming a metal pattern, the method comprising:
coating a photoresist composition on a base substrate having a metal layer and forming a photoresist film, the photoresist composition comprising 5% to 50% by weight of an alkali-soluble resin, 0.5% to 30% by weight of a quinone diazide compound, 0.1% to 15% by weight of a curing agent, and a remainder of an organic solvent;
patterning the photoresist film to form a photo pattern;
heating the photo pattern to form a baked pattern;
patterning the metal layer using the baked pattern to form a metal pattern.

11. The method of claim 10, further comprising exposing the entire photo pattern to a light before heating the photo pattern to form the baked pattern.

12. The method of claim 10, wherein the photoresist composition further comprises 0.01% to 10% by weight of a photo-acid generator.

13. A method of manufacturing a display substrate, the method comprising:
coating a photoresist composition on a base substrate comprising a gate metal layer to form a first photoresist film, the photoresist composition comprising 5% to 50% by weight of an alkali-soluble resin, 0.5% to 30% by weight of a quinone diazide compound, 0.1% to 15% by weight of a curing agent, and a remainder of an organic solvent;
patterning the first photoresist film to form a first photo pattern;
heating the base substrate comprising the first photo pattern to form a first baked pattern;
patterning the gate metal layer using the first baked pattern to form a gate electrode.

14. The method of claim 13, further comprising exposing the entire first photo pattern to a light before heating the base substrate comprising the first photo pattern.

15. The method of claim 13, wherein the photoresist composition further comprises 0.01% to 10% by weight of a photo-acid generator.

16. The method of claim 13, further comprising:
forming a data metal layer on the base substrate comprising the gate electrode;
forming a second photoresist film on the data metal layer using the photoresist composition;
pattering the second photoresist film to form a second photo pattern;
heating the base substrate comprising the second photo pattern to form a second baked pattern; and
patterning the data metal layer using the second baked pattern to form a source electrode and a drain electrode.

17. The method of claim 16, further comprising exposing the entire second photo pattern to a light before heating the base substrate comprising the second photo pattern.

18. The method of claim 16, wherein the second photo pattern comprises a first portion being formed on a source electrode portion and a drain electrode portion, and comprising a first thickness, and a second portion being formed between the source electrode portion and drain electrode portion and comprising a second thickens.

19. The method of claim 16, wherein the photoresist composition further comprises 0.01% to 10% by weight of a photo-acid generator.
